(19) United States
(12) Patent Application Publication
(10) Pub. No.: US 2008/0054268 A1
(43) Pub. Date: Mar. 6, 2008

(54) DISPLAY DEVICE AND METHOD OF MANUFACTURING THE DISPLAY DEVICE

(75) Inventor: Takuji IMAMURA, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-Ku (JP)

(21) Appl. No.: 11/848,749

(22) Filed: Aug. 31, 2007

(30) Foreign Application Priority Data
Sep. 4, 2006 (JP) 2006-239181

(51) Int. Cl. H01L 29/04; H01L 21/84

(52) U.S. Cl. 257/72; 438/149; 257/E29.003; 257/E21.703

(57) ABSTRACT

A display device according to an embodiment of the present invention includes: an interlayer insulating film; a signal line formed above the interlayer insulating film in the display region and supplying a signal or power from a peripheral region to a TFT; a passivation film formed above the signal line; an organic planarization film formed in the display region above the passivation film; and an upper conductive film 15 formed above the organic planarization film, two or more inorganic insulating films being formed between the signal line and the upper conductive film in a non-planarized region not including the planarization film in the peripheral region.

### BACKGROUND OF THE INVENTION

1. Field of the Invention

The present invention relates to a display device and a method of manufacturing the display device.

2. Description of Related Art

Organic EL (electroluminescence) display devices using organic EL elements as light emitting elements arranged in each pixel have attracted attentions as a kind of display device. The organic EL display devices allow a current to flow between upper and lower electrodes that sandwich an organic EL layer to let the organic EL layer emit light. The organic EL element is sandwiched between an anode made of a transparent electrode and a metal-made cathode.

In general active matrix type organic EL display devices, a thin film transistor (hereinafter referred to as “TFT”) is used as an active element for driving an organic EL element. An organic EL element including an organic EL layer is formed in each pixel of a pixel driving circuit substrate including the TFT (hereinafter referred to as “TFT substrate”). In addition, the organic EL layer including the organic EL element is formed on a circuit layer where a pixel circuit including the TFT on a glass substrate is formed. The organic EL layer and the circuit layer are electrically connected together through a contact portion.

In general, the organic EL layer has a film thickness of several μm or less. For example, the film thickness is as small as several tens of nm to several hundreds of nm. Further, the organic EL layer is formed on the TFT substrate. Thus, if a base surface of the formed TFT substrate where the organic EL layer is formed is not flat enough, there arises a problem in that the organic EL layer cannot be formed with a uniform film thickness. That is, flatness of the circuit layer below the organic EL layer is very important.

To overcome the problem, Japanese Unexamined Patent Application Publication Nos. 2002-076346, 2002-202735, and 2002-215063 disclose a technique of forming a planarization film in a pixel portion of a TFT substrate for the purpose of planarizing a base surface of an organic EL layer. More specifically, the planarization film is formed as an insulating layer below a transparent electrode (anode) of the TFT substrate. In addition, Japanese Unexamined Patent Application Publication No. 2000-349300 discloses a technique of forming an insulating layer that is a laminate of an inorganic insulating film and an organic resin film, below the transparent electrode of the TFT.

As the planarization film, an organic insulating film made of a polyimide resin or acrylic resin is mainly used because of high flatness. However, the above organic insulating film contains active impurities and exhibits high hygroscopicity as its characteristics. This causes a problem that moisture or impurities in the organic insulating film infiltrate into the organic EL layer to thereby lower insulating property or reliability of the organic EL layer.

To solve the above problem, according to the structure as disclosed in Japanese Unexamined Patent Application Publication Nos. 2005-164818 and 2006-066206, as shown in FIG. 8, planarization film is separated between a display region 111 and a peripheral region 112 of a TFT substrate 110, and a non-planarized region 300 including no planarization film is formed in a part of the peripheral region 112. This structure prevents reduction in reliability due to moisture or impurities that leak from the organic EL layer.

However, the inventors of the present invention have found that the techniques of the related art involve the following problems. Referring to FIG. 9, the problems of the related art are described below. FIG. 9 is a sectional view of the structure of the TFT substrate 110 in the non-planarized region 300 of FIG. 8. FIG. 9 shows a laminate structure on a gate insulating film 20. Agate line 21 is formed on the gate insulating film 20. Then, a signal line 23 and the gate line 21 are connected through a contact hole 28 formed in an interlayer insulating film 22. Further, a passivation film 24 is formed to cover the signal line 23, and an upper conductive film 25 is formed thereon. Here, the signal line 23 is a line to supply a power supply signal or a control signal of a TFT. The upper conductive film 25 forms an anode that overlies the organic EL layer out of the two electrodes sandwiching the organic EL layer.

As shown in FIG. 9, in the structure of the related art, a single interlayer insulating film 22 is formed between the upper conductive film 25 and the signal line 23. The thickness of the passivation film 24 is as small as 300 nm or less, so a electrical breakdown strength may be lowered between the upper conductive film 25 and the signal line 23 (a portion indicated by the arrow of FIG. 9, for example) due to variations in manufacturing process or the like. This leads to a problem that the upper conductive film 25 and the signal line 23 are short-circuited, and a yield or reliability of the organic EL display device lowers.

### SUMMARY OF THE INVENTION

The present invention has been accomplished with a view to solving the above problems. The invention is directed to a display device that realizes high yield and reliability, and a method of manufacturing the display device.

According to a first aspect of the present invention, a display device including a display region and a peripheral region formed outside the display region, includes: a substrate; a TFT formed in the display region of the substrate; an interlayer insulating film formed above the TFT; a line formed above the interlayer insulating film in the display region and supplying a signal or power from the peripheral region to the TFT; a passivation film formed above the line; a planarization film formed above the passivation film in the display region; an upper conductive film formed above the planarization film; and two or more inorganic insulating films formed between the line and the upper conductive film in a non-planarized region not including the planarization film in the peripheral region.

According to a second aspect of the present invention, a manufacturing method of a display device including a display region and a peripheral region formed outside the display region, includes: forming a TFT in the display region above a substrate; forming an interlayer insulating film above the TFT; forming a line above the interlayer insulating film in the display region, the line supplying a signal or power from the peripheral region to the TFT; forming a passivation film above the line; forming a planarization film above the passivation film in the display region; and forming an upper conductive film above the planarization film, two or more inorganic insulating films being formed between the line and the upper conductive film in a non-planarized region not including the planarization film in the peripheral region.

According to the present invention, it is possible to provide a display device that realizes high yield and reliability, and a method of manufacturing the display device.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIGS. 1A and 1B are plan views of a TFT substrate used in a display device according to the present invention;

FIG. 2 is a sectional view of the structure of a TFT of the TFT substrate according to a first embodiment of the present invention;

FIGS. 3A to 3D are sectional views of a manufacturing process of a non-planarized region of the TFT substrate of the first embodiment;

FIG. 4 is a sectional view of the structure of a display region where the TFT is formed;

FIG. 5 is a sectional view of the non-planarized region of the TFT substrate of the first embodiment;

FIG. 6 is a sectional view of a region including the non-planarized region of the TFT substrate of the first embodiment;

FIG. 7 is a sectional view of a non-planarized region of a TFT substrate according to a second embodiment of the present invention;

FIG. 8 is a plan view of a light emitting display device; and

FIG. 9 is a sectional view of a non-planarized region of a TFT substrate of the related art.

### DESCRIPTION OF THE PREFERRED EMBODIMENTS

Hereinafter, preferred embodiments of the present invention will be described. Some components are omitted or simplified in the following description and the accompanying drawings as appropriate, and repetitive description of the same components or the like is omitted if not necessary for ease of illustration.

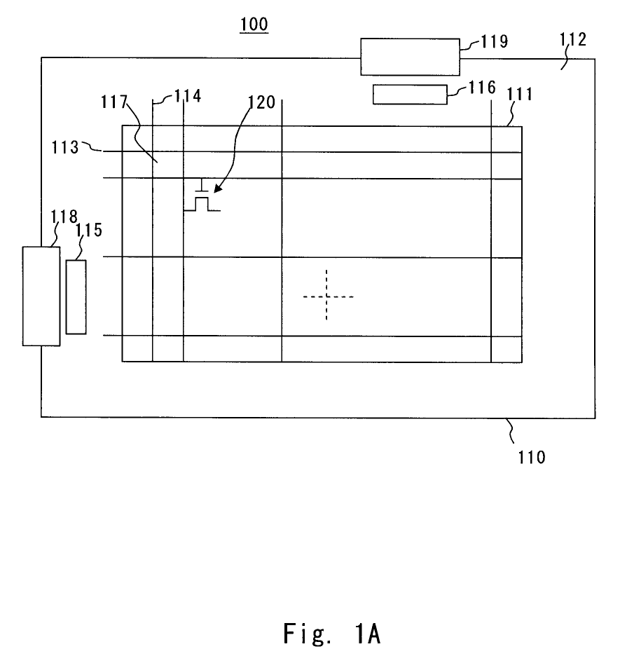

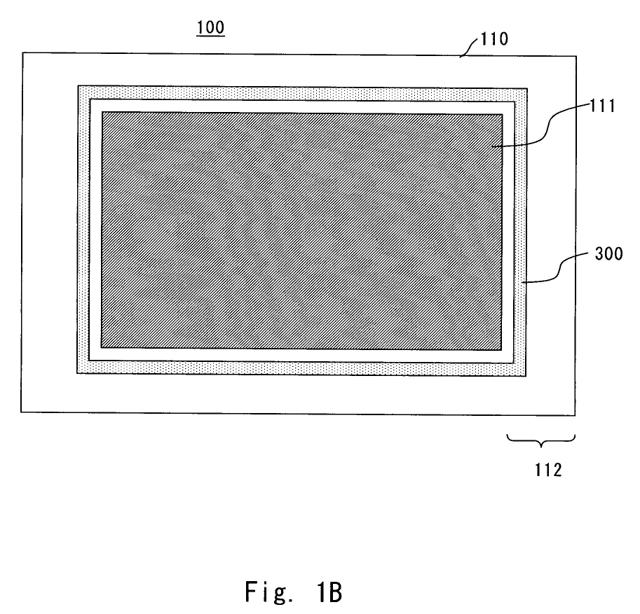

To begin with, a TFT substrate used in a display device according to the present invention is described. It is assumed that a display device 100 of the present invention is an organic EL display device. FIG. 1A is a front view of the structure of TFT substrate used in the organic EL display device. This structure applies to first and second embodiments. The organic EL display device of FIGS. 1A and 1B includes a TFT substrate 110 made of glass or the like. FIG. 1B shows a display region of the TFT substrate of FIG. 1A. The TFT substrate 110 is, for example, a TFT array substrate having TFTs arrayed thereon.

The TFT substrate 110 includes a display region 111 and a peripheral region 112 surrounding the display region 111. As shown in FIG. 1B, the display region 111 is formed into a rectangular shape. The peripheral region 112 has a frame-like shape to surround the display region 111. In the peripheral region 112, a frame-like sealing material is formed to bond the TFT substrate 110 and an opposing substrate. As a result, an organic EL layer is sealed. Further, in the peripheral region 112, a non-planarized region 300 including no planarization film is formed. The non-planarized region 300 has a frame-like shape to surround the display region 111. In the non-planarized region 300, the planarization film is removed as described later. That is, the non-planarized region 300 has a groove where the planarization film is not formed. Incidentally, the non-planarized region 300 is formed, for example, inside the sealing material.

As shown in FIG. 1A, the display region 111 includes plural scanning signal lines 113 and plural display signal lines 114. The plural scanning signal lines 113 extend in parallel. Likewise, the plural display signal lines 114 extend in parallel. The scanning signal lines 113 and the display signal lines 114 cross each other. Each scanning signal line 113 and each display signal line 114 are orthogonal to each other. In addition, a region surrounded by the scanning signal line 113 and the display signal line 114 adjacent to each other becomes a pixel 117. Thus, the pixels 117 are arranged in matrix on the TFT substrate 110.

The peripheral region 112 of the TFT substrate 110 includes a scanning signal driving circuit 115 and a display signal driving circuit 116. The scanning signal lines 113 extend from the display region 111 up to the peripheral region 112. The scanning signal lines 113 are connected to the scanning signal driving circuit 115 at the end of the TFT substrate 110. Likewise, the display signal lines 114 extend from the display region 111 up to the peripheral region 112. The display signal lines 114 are connected to the display signal driving circuit 116 at the end of the TFT substrate 110. An external line 118 is connected near the scanning signal driving circuit 115. Moreover, an external line 119 is connected near the display signal driving circuit 116. The external lines 118 and 119 are constituted of, for example, a wiring substrate such as an FPC (Flexible Printed Circuit).

Various signals are externally supplied to the scanning signal driving circuit 115 and the display signal driving circuit 116 through the external lines 118 and 119. The scanning signal driving circuit 115 supplies a gate signal (scanning signal) to the scanning signal lines 113 in accordance with an external control signal. The scanning signal lines 113 are selected one by one in accordance with the gate signal. The display signal driving circuit 116 supplies a display signal to the display signal lines 114 in accordance with externally supplied control signals or display data. As a result, a display voltage corresponding to the display data can be applied to each pixel 117.

In each pixel 117, at least one TFT 120 is formed. The TFT 120 is formed in the vicinity of an intersection of the display signal lines 114 with the scanning signal lines 113. The TFT 120 is, for example, a switching (SW) thin film transistor. The TFT 120 supplies a display voltage to a driving TFT. Then, the driving TFT supplies a drive current corresponding to the display voltage to a pixel electrode. That is, the TFT 120 as a switching element is turned on in accordance with a gate signal (scanning signal) from the scanning signal lines 113. As a result, a display voltage is applied to the driving TFT connected to a drain electrode of the TFT 120 from the display signal lines 114. Then, the driving TFT is connected with a power supply voltage and the pixel electrode, and supplies a drive current corresponding to the display voltage to the pixel electrode. In other words, the scanning signal lines 113 are signal lines to supply a gate signal (scanning signal) to the TFT 120, and the display signal lines 114 are signal lines to supply a source signal (display voltage).

The pixel electrode is a cathode; the cathode and an opposing electrode as an anode sandwich an organic EL layer of the organic EL display device. A current corresponding to the display voltage flows between the pixel electrode and the opposing electrode, and the organic EL layer emits light. Here, the pixel electrode underlies the organic EL layer, and the opposing electrode overlies the organic EL layer. As described above, an organic EL element including an organic EL layer is formed in each pixel 117 of the TFT array substrate. Hence, a display voltage applied to the TFT 120 of each pixel 117 is controlled to thereby control an amount of emitted light from each organic EL element. That is, if a display voltage is applied to the pixels 117 at different levels, a desired image can be displayed.

### First Embodiment

Next, an example of a TFT substrate according to a first embodiment of the present invention is described. A feature of the first embodiment resides in two or more inorganic insulating films formed between signal lines for supplying signals, power, or the like to each TFT from the peripheral region 112 and an upper conductive film in the non-planarized region 300 of the TFT substrate. The formation of these films makes it possible to improve a electrical breakdown strength between the signal line and the upper conductive film in the non-planarized region 300 of the TFT substrate 110.

First of all, structure and manufacturing method of the TFT 120 in each pixel are described. Incidentally, the following description is directed to a top-gate type TFT that is applied to the organic EL display device for illustrative purposes, but the present invention is applicable to a bottom-gate type TFT as well as the top-gate type TFT.

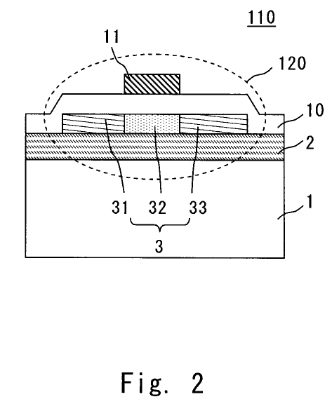

FIG. 2 is a sectional view of the structure of a top-gate type TFT substrate of the first embodiment. The TFT substrate 110 of FIG. 2 includes a glass substrate 1, a diffusion barrier layer 2, a semiconductor layer 3, a gate insulating film 10, and a gate electrode 11. The diffusion barrier layer 2 is formed on the glass substrate 1. The semiconductor layer 3 is formed on the diffusion barrier layer 2. The semiconductor layer 3 is constituted of a channel region 32, a source region 31, and a drain region 33. Further, the semiconductor layer 3, the gate insulating film 10, and the gate electrode 11 constitute the TFT 120. The TFT substrate 110 has plural TFTs 120 arrayed thereon. FIG. 2 is a sectional view of one of the TFTs 120. The gate electrode 11 is placed opposite to the channel region 32. The TFT 120 is covered with a passivation film as described below. Then, various signal lines are connected to the drain region 33, the source region 31, or the like through through-holes formed in the gate insulating film 10 and the passivation film.

Next, a manufacturing method of the TFT is described. First, the glass substrate 1 is cleaned with pure water or acid. As a substrate material for the TFT substrate 110, plastics such as polycarbonate or acrylic resin may be used in place of glass.

After that, the diffusion barrier layer 2 is formed to cover the glass substrate 1. The diffusion barrier layer 2 is formed of SiN (silicon nitride) with chemical vapor deposition (CVD), for example. The diffusion barrier layer 2 insulates the glass substrate 1 from elements formed above the substrate, and prevents impurity diffusion from the glass substrate 1. Further, the diffusion barrier layer 2 functions to suppress an interface state density at the interface with the semiconductor layer 3 formed thereon to stabilize the performance of the TFT 120. Incidentally, the diffusion barrier layer 2 may be made of SiO₂ (silicon oxide) or the like instead of SiN.

Subsequently, the semiconductor layer 3 including the channel region 32, the source region 31, and the drain region 33 is formed in an island-like shape on the diffusion barrier layer 2. First, a material for the semiconductor layer 3 is deposited on the diffusion barrier layer 2. As the semiconductor layer 3, an amorphous silicon film or a micro crystal silicon film can be used, but a high-quality polysilicon film is desirable for improving the performance. However, heat treatment should be performed at 600° C. or higher to directly form the polysilicon film on the substrate by CVD, so it is difficult to form the film on an inexpensive glass substrate. Thus, an amorphous silicon film is desirably formed first on the diffusion barrier layer 2 by low temperature CVD such as plasma CVD, followed by laser annealing to turn the amorphous silicon to a polysilicon film. After that, the semiconductor layer 3 is formed into a desired pattern through a photolithography step, a dry etching step, or the like.

Next, the gate insulating film 10 is formed to cover the semiconductor layer 3. The gate insulating film 10 is made of, for example, SiO₂ (silicon oxide). The gate insulating film 10 has an effect of suppressing an interface state density at the interface with the semiconductor layer 3. Considering thermal strain of the glass of the glass substrate 1, it is desirable to form a film by low temperature CVD. Incidentally, the gate insulating film 10 may be formed of a material other than SiO₂ with a TFT manufacturing method other than the low temperature CVD.

After that, the gate electrode 11 is formed in an island-like shape to cover the channel region 32 through the gate insulating film 10. That is, the gate insulating film 10 is interposed between the gate electrode 11 and the channel region 32, and the gate electrode 11 opposed to the channel region 32 of the semiconductor layer 3 with the gate insulating film 10 interposed therebetween. In other words, the channel region 32 of the semiconductor layer 3 and the gate electrode 11 are opposite to each other across the gate insulating film 10. Upon the formation of the gate electrode 11, an Mo film or the like is formed by sputtering or the like.

Subsequently, the gate electrode 11 is formed in an island-like shape through a photolithography step. To be specific, a photoresist applied onto the Mo film is baked and then masked and exposed with a predetermined pattern. Next, the photoresist is developed with, for example, an organic alkali-based developer and patterned. Moreover, the Mo film is subjected to wet etching with, for example, a mixed solution of a phosphoric acid and a nitric acid to thereby form the gate electrode 11 into a desired pattern shape. Then, the photoresist is removed from the substrate, and the resultant substrate is cleaned.

Next, impurities such as phosphorus (P) and boron (B) are doped to the source region 31 and drain region 33 of the semiconductor layer 3 with the gate electrode 11 used as a mask. A highly doped region is thereby formed in the semiconductor layer 3. As a doping method, ion implantation or ion doping may be used. The TFT 120 is completed through the above steps.

Next, an interlayer insulating film, signal lines, a passivation film, a planarization film, a pixel electrode, an organic EL layer, and an opposing electrode are formed in order on the TFT 120. Description about formation steps thereof is given below.

Although not shown in FIG. 2, the gate electrode 11 extends to a region except an upper region of the channel region 32, and forms a gate line. The gate line is connected to the scanning signal line 113 of FIG. 1A and to the scanning signal driving circuit 115. The scanning signal driving circuit 115 supplies a gate signal (scanning signal) to the gate electrode 11 through the scanning signal line 113 in accordance with an external control signal. That is, a control signal is supplied to the TFT 120 from the scanning signal line 113 connected to the gate electrode 11 through the gate line to thereby control an amount of light emitted from the organic EL element. Here, the scanning signal line 113 is a line to supply a control signal to the TFT 120. In the case of connecting the scanning signal line 113 to the scanning signal driving circuit 115, the scanning signal line 113 is formed to extend from the display region 111 to the peripheral region 112 of the TFT substrate 110.

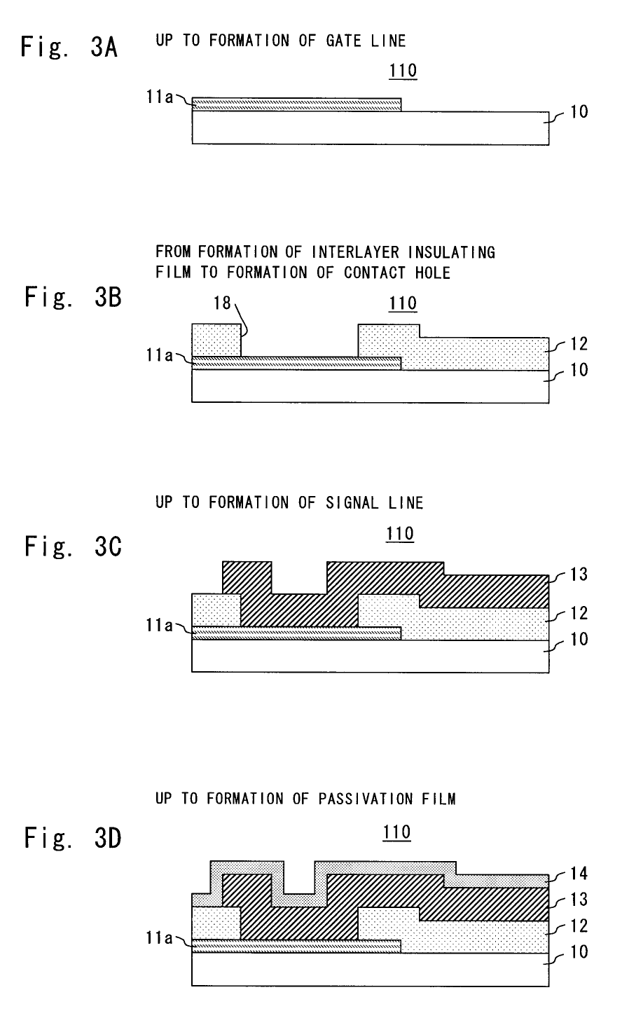

Referring to FIGS. 3A to 3D, steps following the formation of the TFT 120 are described next. That is, a step of forming the gate electrode 11 and gate line 11a and subsequent steps are described. FIGS. 3A to 3D are sectional views of the TFT substrate in the non-planarized region 300 of FIG. 1B. Incidentally, the layers below the gate insulating film 10 are omitted from FIGS. 3A to 3D.

FIG. 3A is a sectional view illustrating a step of forming the gate line 11a on the gate insulating film 10. A manufacturing process up to the formation of the gate insulating film 10 is the same as the method as shown in FIG. 2, so description thereof is omitted here. On the TFT substrate 110 having the gate insulating film 10 formed thereon, for example, gate metal such as Mo is deposited into a film by sputtering or the like. Then, a resist pattern is formed in a photolithography step, and the gate metal is etched in an etching step. After that, a residual resist is removed to complete the gate line 11a. The thus-obtained structure is illustrated in FIG. 3A. The formation step of the gate line 11a is the same as the formation step of the gate electrode 11 as shown in FIG. 2. That is, the gate line 11a extends from the gate electrode 11 of FIG. 2, and is formed together with the gate electrode 11. Incidentally, the TFT 120 is not formed below the gate line 11a.

Referring next to FIG. 3B, description is made of a step of forming the interlayer insulating film 12 to a step of forming the contact hole 18. After the formation of the gate line 11a, the interlayer insulating film 12 is formed to cover the gate line 11a. As the interlayer insulating film 12, for example, an SiO₂ film is used. Considering thermal strain of glass of a substrate material, it is desirable to form the interlayer insulating film 12 by low temperature CVD. However, the present invention is not limited to this method. In addition, the interlayer insulating film 12 may be an inorganic insulating film formed of any other material.

After that, the contact hole 18 for connecting the gate line 11a and the signal line 13 formed above the gate line 11a is formed in the interlayer insulating film 12. The contact hole 18 is formed by removing a resist pattern in a photolithography step and etching the interlayer insulating film 12 in a dry etching step. Subsequently, a residual resist is removed to form the contact hole 18. The thus-obtained structure is shown in FIG. 3B. The contact hole 18 that reaches the gate line 11a is thereby formed.

Referring to FIG. 3C, a step of forming the signal line 13 is described next. After the formation of the contact hole 18, a conductive film is formed with a thickness of 1.0 μm or less by sputtering or the like. Subsequently, a resist pattern is formed through a photolithography step, and the conductive film is patterned into a desired shape through a wet or dry etching step. Then, a residual resist is removed to complete the signal line 13. At the time of forming the conductive film, a material for the conductive film is also filled in the contact hole 18. Therefore, the signal line 13 and the gate line 11a are physically and electrically connected together through the contact hole 18. The thus-obtained structure is illustrated in FIG. 3C. Incidentally, the signal line 13 is not limited to a line connected to the gate line 11a. For example, the signal line 13 may be connected to the source region 31 or drain region 33 of the TFT 120. That is, the signal line 13 can be used as a line electrically connected to the TFT 120. Hence, a gate signal, a source signal, a power supply potential, or the like is applied to the TFT 120 through the signal line 13. The signal line 13 extends from the peripheral region 112 to the display region 111 to supply a signal or power from the peripheral region 112 to the TFT 120, and is positioned above the interlayer insulating film 12 in the display region 111.

Referring to FIG. 3D, a step of forming the passivation film 14 is described next. In this step, the passivation film 14 is formed to cover the signal line 13. The passivation film 14 is an insulating film, for example, an SiN film, which is formed by plasma CVD. Meanwhile, the passivation film 14 is also formed in the display region 111.

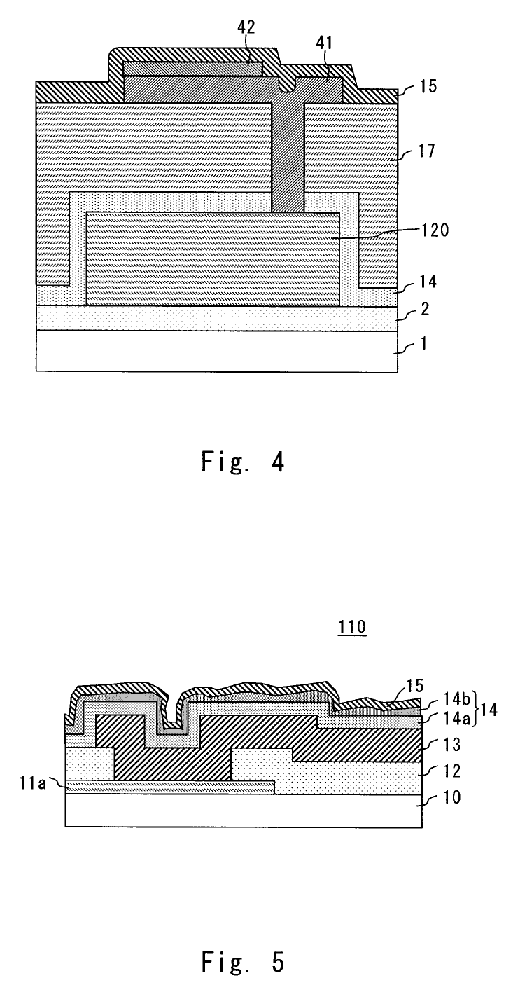

Here, a manufacturing process in the display region is described with reference to FIG. 4. FIG. 4 is a sectional view of the display region 111 where the TFT is formed. First, in the display region 111 having the TFT 120 formed therein, a through-hole for connecting the signal line and the pixel electrode formed above the passivation film 14 is formed. To be specific, a resist pattern is formed on the passivation film 14 through a photolithography step, and the passivation film 14 is etched through dry etching. As a result, the through-hole is formed in the passivation film 14. Thereafter, a residual resist is removed.

After the formation of the through-hole in the passivation film 14, an organic planarization film 17 is formed to smooth the substrate surface. The organic planarization film 17 is formed on the passivation film 14 having the through-hole. Then, a through-hole is formed in the organic planarization film 17 as well. Furthermore, a pixel electrode 41 as a cathode is formed on the organic planarization film 17. The pixel electrode 41 is electrically connected to the TFT 120 through the through-hole. Then, an organic EL layer 42 is formed on the pixel electrode 41. In addition, an upper conductive film 15 including the opposing electrode is formed on the organic EL layer 42. The opposing electrode functions as an anode. Then, the opposing electrode and the pixel electrode 41 are opposite to each other and sandwich the organic EL layer 42. As a result, the organic EL layer 42 emits light with luminance corresponding to a display voltage. The upper conductive film 15 extends, for example, from the peripheral region 112 to the display region 111, and applies a common potential (anode potential) to the opposing electrode (anode) in the pixel. Thus, the upper conductive film 15 is also formed in the non-planarized region 300 of the peripheral region 112.

The organic planarization film 17 may be made of, for example, a polyimide resin or an acrylic resin with a thickness of 1 μm or more. Further, the organic planarization film 17 made of a photosensitive resin can be easily patterned. The organic planarization film 17 is formed throughout the display region 111, for example. Further, as described above, the non-planarized region 300 is defined in the peripheral region 112 to prevent deterioration of the organic EL layer due to moisture. That is, the organic planarization film 17 is removed from a part or all of the peripheral region 112 by a photolithography step. As a result, the non-planarized region 300 is formed inside the sealing material of the peripheral region 112.

In this example, the organic planarization film 17 and the passivation film 14 are formed between the signal line 13 and the upper conductive film 15 in the display region 111. Thus, the signal line 13 and the upper conductive film 15 are not easily short-circuited. However, in the peripheral region 112, the non-planarized region 300 not including the thick organic planarization film 17 is formed. In this case, the signal line 13 and the upper conductive film 15 might be short-circuited in the non-planarized region 300 due to variations in manufacturing process, leading to defective display in the organic EL display device. To overcome the problem, in this embodiment, the passivation film 14 as shown in FIG. 3D is formed in two steps. That is, the passivation film 14 is formed using two inorganic insulating films.

To be specific, as shown in FIG. 5, the passivation film 14 is composed of a first passivation film 14a formed in a first step and a second passivation film 14b formed in a second step. Incidentally, FIG. 5 is a sectional view of the structure of the TFT substrate 110 in the non-planarized region 300. In FIG. 5, the passivation film 14 has a two-layer structure of the first passivation film 14a and the second passivation film 14b. In addition, the total thickness of the first passivation film 14a and the second passivation film 14b is 300 nm or more. In FIG. 5, the passivation film 14 has the two-layer structure, but two or more layers may be laminated. Further, the passivation films 14a and 14b may be formed of different materials, not limited to the same material. For example, a silicon nitride layer and a silicon oxide layer can be used. Further, the passivation films 14a and 14b may differ from each other in film thickness. Incidentally, the structure of layers below the gate insulating film 10 is not shown in FIG. 5.

The passivation films 14a and 14b are formed by, for example, CVD. In the first embodiment, it is important that the passivation film 14 has a laminate structure of two or more layers, and the total thickness is 300 nm or more. Thus, there is no particular limitation on a manufacturing method thereof. The above manufacturing method is employed by way of example, and it is possible to use any other method that could be conceived by those skilled in the art, who are involved with manufacturing of TFTs.

As described above, if the passivation film 14 has the laminate structure of two or more layers with the total thickness of 300 nm or more, a electrical breakdown strength between the upper conductive film 15 and the signal line 13 can be improved to prevent the upper conductive film 15 and the signal line 13 from being short-circuited. Incidentally, the upper conductive film 15 is, for example, a transparent conductive film made of ITO or the like. The upper conductive film 15 is patterned by any known sputtering method and a photolithography step. Incidentally, the organic EL layer and the pixel electrode between the passivation film 14 and the upper conductive film 15 can be formed by any known method with any known material, so description thereof is omitted. Further, a partition may be formed to define each pixel 117 or divide the organic EL layer.

Incidentally, there is no particular limitation on the signal line 13 formed below the passivation film 14 having the laminate structure. For example, the signal line 13 is not limited to the line connected to the scanning signal line 113 but may be a signal line 13 for supplying a power supply voltage. That is, the signal line 13 may be any line that is electrically connected to the TFT 120. Needless to say, the signal line may be connected to a driving TFT or other such TFTs in place of the switching TFT 120. Then, a power supply or signals are supplied to the TFT 120 in the pixel 117 through the signal line 13. In this case, the signal line 13 extends from the peripheral region 112 to the display region 111 and is connected to the TFT 120. In the non-planarized region 300, the signal line 13 is formed between the passivation film 14 and the interlayer insulating film 12.

Then, the passivation film 14 having the laminate structure is formed above the TFT 120 and the signal line 13. Thus, it is possible to suppress occurrences of an insulation failure between the signal line 13 formed below the passivation film 14 and the upper conductive film 15 formed thereon in the non-planarized region 300. That is, the passivation film 14 has a laminate structure. Thus, even if the signal line 13 is formed above the interlayer insulating film 12 or the gate insulating film 10, occurrences of an insulation failure are suppressed. Further, a conductive film formed on the passivation film 14 is not limited to the upper conductive film 15. For example, a conductive film connected to the other electrode in the pixel may be used instead. Hence, the passivation film 14 composed of two inorganic insulating films has only to be formed between the upper conductive film 15 and the lower signal line 13 in the non-planarized region 300. Moreover, the total thickness of the passivation film 14 composed of two inorganic insulating films is set to 300 nm or more. The two inorganic insulating films are interposed between the signal line 13 and the upper conductive film 15 over the non-planarized region 300. As a result, occurrences of an insulation failure can be further suppressed.

Incidentally, in the above description, the non-planarized region 300 is formed in a part of the peripheral region 112 but may be formed in almost all of the peripheral region 112. That is, the non-planarized region 300 may be formed throughout the peripheral region 112. In this case, the organic planarization film 17 is completely removed outside the display region 111 to form the non-planarized region 300. Then, the passivation film 14 of the laminate structure is formed over the peripheral region 112. Incidentally, an inorganic planarization film may be used in place of the organic planarization film 17. As described above, the planarization film is formed to thereby smooth the surface where the organic EL element is formed. Accordingly, display quality can be improved.

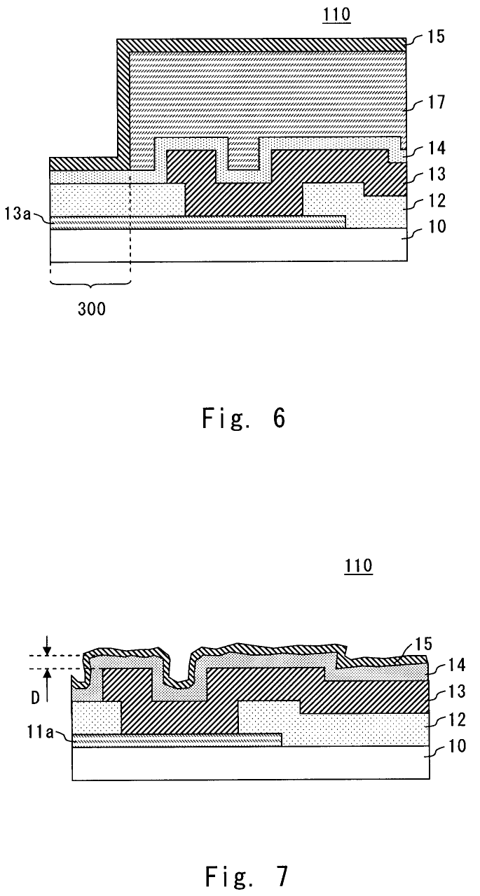

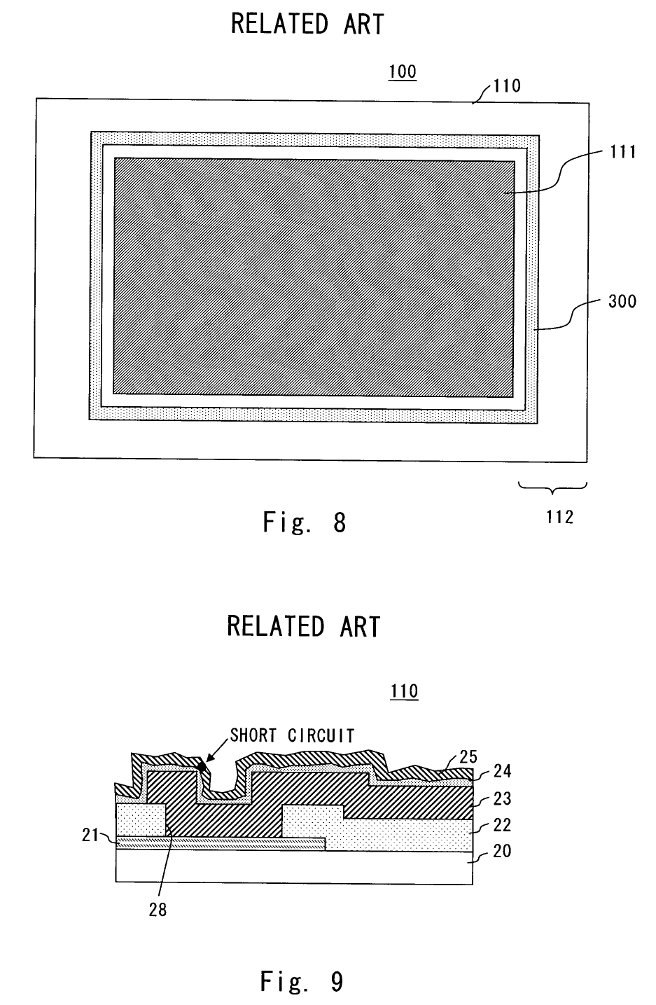

As shown in FIG. 6, a signal line 13a may be formed using the layer where the gate line 11a is formed, in the non-planarized region 300. That is, a signal line in the non-planarized region 300 is formed by use of the signal line 13a; the signal line 13a and the gate line 11a are formed using the same layer. The signal line 13a extends from the non-planarized region 300 up to a region where the organic planarization film 17 is formed. A contact hole is formed in the interlayer insulating film 12 at the region where the organic planarization film 17 is formed. The signal line 13a under the interlayer insulating film 12 and the signal line 13 on the interlayer insulating film 12 are electrically connected through the contact hole. Signals and power supply potential are applied through the signal line 13a to the signal line 13 in the pixel 117. In such structure, the inorganic insulating films of the passivation film 14 and the interlayer insulating film 12 are formed between the signal line 13a and the upper conductive film 15 in the non-planarized region 300. That is, the signal line 13a is formed using the layer where the gate line 11a is formed in the non-planarized region 300 to thereby form the laminate structure of two or more insulating films between the upper conductive film 15 and the signal line 13a. In this case, occurrences of an insulation failure can be suppressed even if the passivation film 14 does not have the two-layer structure. That is, even if the passivation film 14 of a single-layer structure is used, two inorganic insulating films are formed between the upper conductive film 15 and the signal line 13a in the non-planarized region 300. Hence, it is possible to simplify the manufacturing process as well as suppress occurrences of an insulation failure. In this case, only the signal line 13a is formed instead of forming the signal line 13 in the non-planarized region 300. Incidentally, the structure of layers below the gate insulating film 10 is not shown in FIG. 6.

### Second Embodiment

Referring to FIG. 7, a second embodiment of the present invention is described next. FIG. 7 is a sectional view of a peripheral region including no planarization film according to the second embodiment. The same components as those of the first embodiment are denoted by reference numerals identical with those of FIGS. 1A to 6. A feature of the second embodiment as shown in FIG. 7 is that the film thickness D of the passivation film 14 is 300 nm or more. In this embodiment, the passivation film 14 is formed using a single insulating film. The other components and manufacturing methods are the same as those of the first embodiment, so description thereof is omitted here.

Owing to the above structure, the second embodiment attains similar effects to those of the first embodiment. Moreover, the first and second embodiments may be used in combination.

The present invention is not limited to the organic EL display device and is applicable to any light emitting display device where a planarization film is formed below a light emitting layer. For example, the present invention is applicable to an inorganic EL display device a side from the organic EL display device. In this case, the upper conductive film 15 is an anode or a cathode connected to the EL layer.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A display device including a display region and a peripheral region formed outside the display region, comprising:
a substrate;
a TFT formed in the display region of the substrate;
an interlayer insulating film formed above the TFT;
a line formed above the interlayer insulating film in the display region and supplying a signal or power from the peripheral region to the TFT;
a passivation film formed above the line;
a planarization film formed above the passivation film in the display region;
an upper conductive film formed above the planarization film; and
two or more inorganic insulating films formed between the line and the upper conductive film in a non-planarized region not including the planarization film in the peripheral region.

2. The display device according to claim 1, wherein the total thickness of the two or more inorganic insulating films is substantially 300 nm or more.

3. The display device according to claim 1, further comprising:
a gate line formed below the interlayer insulating film and connected to the TFT,
wherein the line of the non-planarized region and the gate line are formed using the same layer, and
the two or more inorganic insulating films between the line and the upper conductive film include the interlayer insulating film and the passivation film in the non-planarized region.

4. The display device according to claim 2, further comprising:
a gate line formed below the interlayer insulating film and connected to the TFT,
wherein the line of the non-planarized region and the gate line are formed using the same layer, and
the two or more inorganic insulating films between the line and the upper conductive film include the interlayer insulating film and the passivation film in the non-planarized region.

5. The display device according to claim 1, wherein the line of the non-planarized region is formed above the interlayer insulating film, and the passivation film includes two or more inorganic insulating films.

6. The display device according to claim 2, wherein the line of the non-planarized region is formed above the interlayer insulating film, and the passivation film includes two or more inorganic insulating films.

7. A manufacturing method of a display device including a display region and a peripheral region formed outside the display region, comprising:
forming a TFT in the display region above a substrate;
forming an interlayer insulating film above the TFT;
forming a line above the interlayer insulating film in the display region, the line supplying a signal or power from the peripheral region to the TFT;
forming a passivation film above the line;
forming a planarization film above the passivation film in the display region; and
forming an upper conductive film above the planarization film,
two or more inorganic insulating films being formed between the line and the upper conductive film in a non-planarized region not including the planarization film in the peripheral region.

8. The manufacturing method of a display device according to claim 7, wherein the total thickness of the two or more inorganic insulating films is substantially 300 nm or more.

9. The manufacturing method of a display device according to claim 7, further comprising:
forming a gate line connected to the TFT prior to formation of the interlayer insulating film,
wherein the line of the non-planarized region and the gate line are formed using the same layer, and
the two or more inorganic insulating films between the line and the upper conductive film include the interlayer insulating film and the passivation film in the non-planarized region.

10. The manufacturing method of a display device according to claim 8, further comprising:
forming a gate line connected to the TFT prior to formation of the interlayer insulating film,
wherein the line of the non-planarized region and the gate line are formed using the same layer, and
the two or more inorganic insulating films between the line and the upper conductive film include the interlayer insulating film and the passivation film in the non-planarized region.

11. The manufacturing method of a display device according to claim 7, wherein the line of the non-planarized region is formed above the interlayer insulating film, and the passivation film includes two or more inorganic insulating films.

12. The manufacturing method of a display device according to claim 8, wherein the line of the non-planarized region is formed above the interlayer insulating film, and the passivation film includes two or more inorganic insulating films.
